(19) United States
(12) Patent Application Publication
(10) Pub. No.: US 2023/0238485 A1
(43) Pub. Date: Jul. 27, 2023

(54) LIGHT EMITTING DEVICE AND METHOD OF MANUFACTURING THE SAME

(71) Applicant: SAMSUNG ELECTRONICS CO., LTD., Suwon-si (KR)

(72) Inventors: Jonguk SEO, Hwaseong-si (KR); Donggun LEE, Yongin-si (KR); Jonghyun LEE, Suwon-si (KR); Myunggoo CHEONG, Suwon-si (KR); Seungwan CHAE, Yongin-si (KR); Youngjo TAK, Seongnam-si (KR)

(73) Assignee: SAMSUNG ELECTRONICS CO., LTD., Suwon-si (KR)

(21) Appl. No.: 17/900,269

(22) Filed: Aug. 31, 2022

(30) Foreign Application Priority Data
Jan. 21, 2022 (KR) 10-2022-0009235

(51) Int. Cl. H01L 33/32; H01L 33/10; H01L 33/38; H01L 33/62

(52) U.S. Cl. CPC H01L 33/32; H01L 33/10; H01L 33/382; H01L 33/62

(57) ABSTRACT

A light emitting device includes a first light transmitting layer, a second light transmitting layer provided on the first light transmitting layer, a plurality of mesa structures provided on the second light transmitting layer and configured to generate light in an ultraviolet band, and passivation patterns provided on side surfaces of the plurality of mesa structures. Each of the plurality of mesa structures includes a first epitaxial pattern including an aluminum gallium nitride, a second epitaxial pattern provided on the first epitaxial pattern and including an aluminum gallium nitride, a third epitaxial pattern provided on the second epitaxial pattern and including an aluminum gallium nitride, and a fourth epitaxial pattern provided on the third epitaxial pattern and including a gallium nitride. A horizontal width of each of the plurality of mesa structures is in a range of about 5 μm to about 30 μm.

### CROSS-REFERENCE TO RELATED APPLICATION

This application is based on and claims priority under 35 U.S.C. § 119 to Korean Patent Application No. 10-2022-0009235, filed on Jan. 21, 2022, in the Korean Intellectual Property Office, the disclosure of which is incorporated by reference herein in its entirety.

### BACKGROUND

The present disclosure relates generally to a light emitting device and a method of manufacturing the light emitting device.

Light emitting diode (LED) chips have several advantages such as low power consumption, high brightness, and a long lifespan, thereby being widely used as light sources.

Recently, interest in ultraviolet (UV) LEDs used for sterilization and disinfection of fluids such as air and water has increased.

Also, mercury lamps have been mainly used as light sources for various UV applications. The UV LEDs that have been recently developed have small volume, are light and compact, and have a lifespan five or more times longer compared to mercury UV lamps. Compared to mercury lamps, UV LEDs are freely designed with respect to the light emission wavelength, generate low heat, and have excellent energy efficiency. In addition, UV LEDs do not generate ozone, which is harmful to the human body and environment, and do not require use of heavy metal such as mercury.

An UV LED chip includes p-GaN formed on pAlGaN to form an ohmic contact, and an absorption rate of UV light is high due to bandgap characteristics of p-GaN. Accordingly, light extraction efficiency of the UV LED chip is reduced.

In addition, because AlN is not bonded onto a roughened sapphire layer, a concave-convex structure for preventing total reflection between a sapphire layer and an AlN layer may not be formed either.

### SUMMARY

Example embodiments provide a light emitting device with increased light extraction efficiency and a method of manufacturing the light emitting device.

Example embodiments also provide a light emitting device on which a mesa structure having a very narrow horizontal width is formed, and an oxide such as Al₂O₃ or SiO₂ is formed on a side surface of the mesa structure through a thermal oxidation process. Accordingly, light emitted at an angle greater than a critical angle is reflected by an oxide layer and directed at an angle less than the critical angle.

Additional aspects will be set forth in part in the description which follows and, in part, will be apparent from the description, or may be learned by practice of the presented embodiments.

According to an aspect of an example embodiment, a light emitting device may include a first light transmitting layer, a second light transmitting layer provided on the first light transmitting layer, a plurality of mesa structures provided on the second light transmitting layer and configured to generate light in an ultraviolet band, and passivation patterns provided on side surfaces of the plurality of mesa structures. Each of the plurality of mesa structures may include a first epitaxial pattern including an aluminum gallium nitride, a second epitaxial pattern provided on the first epitaxial pattern and including an aluminum gallium nitride, a third epitaxial pattern provided on the second epitaxial pattern and including an aluminum gallium nitride, and a fourth epitaxial pattern provided on the third epitaxial pattern and including a gallium nitride. A horizontal width of each of the plurality of mesa structures may be in a range of about 5 μm to about 30 μm.

According to an aspect of an example embodiment, a light emitting device may include a first light transmitting layer including sapphire, a second light transmitting layer including an aluminum nitride and provided on the first light transmitting layer, a first epitaxial layer provided on the second light transmitting layer and including a plurality of first epitaxial patterns separated from each other in a first direction, a plurality of second epitaxial patterns provided on the plurality of first epitaxial patterns, separated from each other in the first direction, and including a multiple quantum well (MQW) structure, a plurality of third epitaxial patterns provided on the plurality of second epitaxial patterns and separated from each other in the first direction, and a plurality of fourth epitaxial patterns provided on the plurality of third epitaxial patterns and separated from each other in the first direction. A width of each of the plurality of first epitaxial patterns in the first direction may be in a range of about 5 μm to about 30 μm.

According to an aspect of an example embodiment, a light emitting device may include a first light transmitting layer having a flat plate shape, a second light transmitting layer provided on the first light transmitting layer and having a flat plate shape, a first epitaxial layer provided on the second light transmitting layer and including a plurality of first epitaxial patterns separated from each other in a first direction, a plurality of second epitaxial patterns provided on the plurality of first epitaxial patterns, separated from each other in the first direction, and including a MQW structure, a plurality of third epitaxial patterns provided on the plurality of second epitaxial patterns and separated from each other in the first direction, and a plurality of fourth epitaxial patterns provided on the plurality of third epitaxial patterns and separated from each other in the first direction. The plurality of first epitaxial patterns, the plurality of second epitaxial patterns, and the plurality of third epitaxial patterns each may include an aluminum gallium nitride, the plurality of fourth epitaxial patterns each may include a gallium nitride, the plurality of first epitaxial patterns, the plurality of second epitaxial patterns, the plurality of third epitaxial patterns, and the plurality of fourth epitaxial patterns form a plurality of mesa structures separated from each other, and a width of each of the plurality of mesa structures in the first direction may be in a range of about 5 μm to about 30 μm.

According to an aspect of an example embodiment, a method of manufacturing a light emitting device may include forming a first epitaxial layer, a second epitaxial layer, a third epitaxial layer, and a fourth epitaxial layer on a first light transmitting layer and a second light transmitting layer, etching the first to fourth epitaxial layers to form a plurality of mesa structures including a first epitaxial pattern, a second epitaxial pattern, a third epitaxial pattern, and a fourth epitaxial pattern, wherein the plurality of mesa structures are separated from each other in a first direction and widths of the plurality of mesa structures are in a range of about 5 μm to about 30 μm, forming a passivation layer on the plurality of mesa structures through a thermal oxidation process, etching the passivation layer, thereby forming passivation patterns that cover side surfaces of the plurality of mesa structures, exposing upper surfaces of the plurality of mesa structures, and exposing the first epitaxial layer between the plurality of mesa structures, and forming a contact layer in contact with the first epitaxial layer.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a cross-sectional view illustrating a light emitting device according to an example embodiment;

FIG. 2 is an enlarged cross-sectional view of a portion of FIG. 1 according to an example embodiment;

FIG. 3 is a graph illustrating external quantum efficiency of a light emitting device according to horizontal widths of a plurality of mesa structures, according to an example embodiment;

FIG. 4 is a partial cross-sectional view of passivation patterns according to an example embodiment;

FIG. 5 is a plan view illustrating a light emitting device according to an example embodiment;

FIG. 6 is a plan view illustrating a light emitting device according to an example embodiment;

FIG. 7 is a cross-sectional view illustrating a light emitting device according to an example embodiment;

FIG. 8 is an enlarged cross-sectional view of a portion of FIG. 7 according to an example embodiment;

FIG. 9 is a flowchart of a method of manufacturing a light emitting device, according to an example embodiment; and

FIGS. 10, 11, 12, 13, 14 and 15 are cross-sectional views illustrating a method of manufacturing a light emitting device, according to example embodiments.

### DETAILED DESCRIPTION

Hereinafter, embodiments of the disclosure will be described in detail with reference to the accompanying drawings. The same reference numerals are used for the same components in the drawings, and redundant descriptions thereof are omitted.

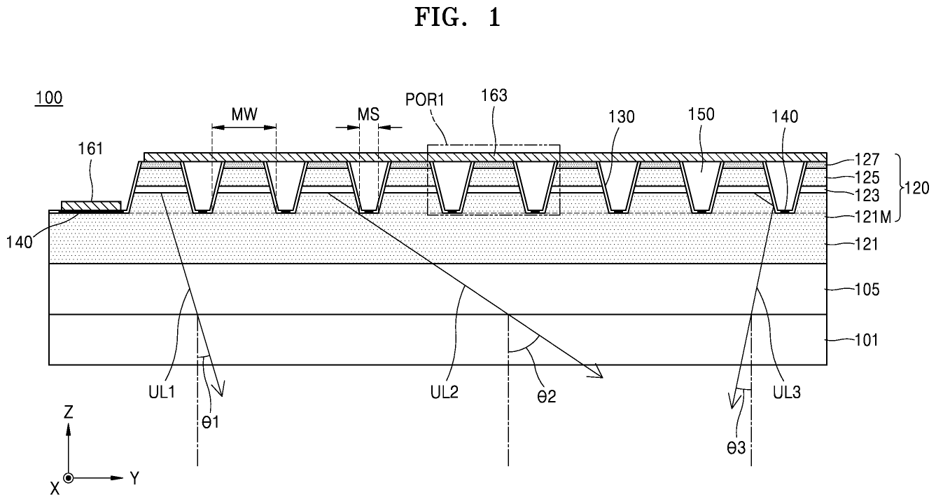

FIG. 1 is a cross-sectional view illustrating a light emitting device 100 according to an example embodiment.

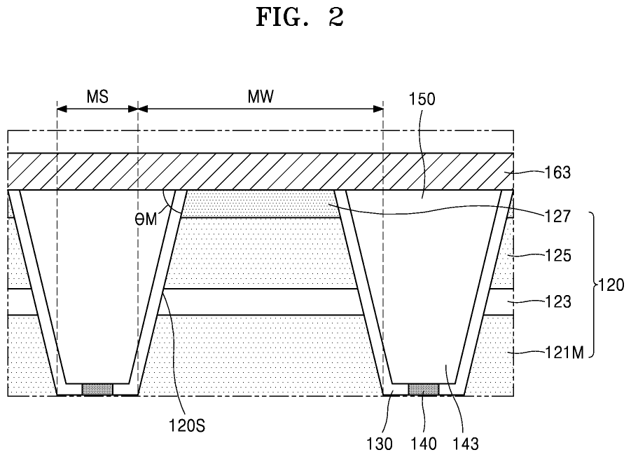

FIG. 2 is an enlarged cross-sectional view of a portion POR1 of FIG. 1 according to an example embodiment.

Referring to FIGS. 1 and 2, the light emitting device 100 may generate lights UL1, UL2, and UL3 based on an external electrical signal. Peak wavelengths of the lights UL1, UL2, and UL3 generated by the light emitting device 100 may be in an ultraviolet band.

According to example embodiments, peak wavelengths of the lights UL1, UL2, and UL3 may be less than or equal to about 400 nm. According to example embodiments, peak wavelengths of the lights UL1, UL2, and UL3 may be less than or equal to about 380 nm. According to example embodiments, peak wavelengths of the lights UL1, UL2, and UL3 may be less than or equal to about 365 nm. According to example embodiments, peak wavelengths of the lights UL1, UL2, and UL3 may be less than or equal to about 350 nm. According to example embodiments, peak wavelengths of the lights UL1, UL2, and UL3 may be less than or equal to about 320 nm. According to example embodiments, peak wavelengths of the lights UL1, UL2, and UL3 may be less than or equal to about 300 nm. According to example embodiments, peak wavelengths of the lights UL1, UL2, and UL3 may be less than or equal to about 280 nm. According to example embodiments, peak wavelengths of the lights UL1, UL2, and UL3 may be less than or equal to about 275 nm. According to example embodiments, peak wavelengths of the lights UL1, UL2, and UL3 may be less than or equal to about 13.5 nm. According to example embodiments, peak wavelengths of the lights UL1, UL2, and UL3 may be less than or equal to about 100 nm.

In one example embodiment, the light emitting device 100 may include a first light transmitting layer 101, a second light transmitting layer 105, a first epitaxial layer 121 including first epitaxial patterns 121M, second epitaxial patterns 123, third epitaxial patterns 125, fourth epitaxial patterns 127, a passivation pattern 130, a contact layer 140, a filling insulating layer 150, a first electrode layer 161, and a second electrode layer 163.

According to example embodiments, the first light transmitting layer 101 may be a growth substrate for providing the first epitaxial layer 121 and the second to fourth epitaxial patterns 123, 125, and 127.

In a non-limiting example, the first light transmitting layer 101 may include a sapphire substrate. A sapphire substrate has electrical insulating properties and is a crystal with Hexa-Rhombo R3c symmetry and has lattice constants of 13.001 Å and 4.758 Å respectively in a c-axis direction and an a-axis direction and has crystal planes of a C(0001) plane, an A(1120) plane, an R(1102) plane, and so on. In this case, the C(0001) plane relatively easily grows a nitride thin film and is stable at a high temperature, and thus, a sapphire substrate is mainly used as a substrate for nitride growth.

In another example, the first light transmitting layer 101 may include a material such as Si, SiC, MgAl₂O₄, MgO, LiAlO₂, LiGaO₂, or GaN.

According to example embodiments, the first light transmitting layer 101 may have a flat plate shape. According to example embodiments, an upper surface and a lower surface of the first light transmitting layer 101 may be substantially flat. According to example embodiments, a thickness of the first light transmitting layer 101 may be substantially constant over the entire surface thereof.

Hereinafter, two directions parallel to the upper surface of the first light transmitting layer 101 are respectively sequentially defined as the X direction and the Y direction, and a direction perpendicular to the upper surface of the first light transmitting layer 101 is defined as the Z direction. The X direction, the Y direction, and the Z direction may be substantially perpendicular to each other. The lower surface of the first light transmitting layer 101 may face the second light transmitting layer 105, and the upper surface of the first light transmitting layer 101 may be opposite to the lower surface thereof. The lights UL1, UL2, and UL3 generated by the light emitting device 100 may be emitted to the outside through the upper surface of the first light transmitting layer 101.

The second light transmitting layer 105 may be a buffer layer for providing the first epitaxial layer 121 and the second to fourth epitaxial patterns 123, 125, and 127. According to example embodiments, the second light transmitting layer 105 may prevent defects (for example, threading dislocations) due to the first light transmitting layer 101 from being transferred to the first epitaxial layer 121 and the second to fourth epitaxial patterns 123, 125, and 127.

According to example embodiments, the second light transmitting layer 105 may include a ceramic material such as AlN. The second light transmitting layer 105 may include an undoped semiconductor material. In a non-limiting example, the second light transmitting layer 105 may include GaN, AlN, InGaN, or so on which are undoped and may be formed at a low temperature of about 500° C. to about 600° C. The second light transmitting layer 105 may have a thickness of several tens to several hundreds of A. Since the second light transmitting layer 105 is not doped, the second light transmitting layer 105 is not separately doped with impurities. Although the second light transmitting layer 105 is not doped, the second light transmitting layer 105 may include impurities at an original concentration level. For example, when a gallium nitride layer is grown by using metal organic chemical vapor deposition (MOCVD), the gallium nitride layer may include Si at a level of about 10¹⁴ to 10¹⁸/cm³. The second light transmitting layer 105 may be omitted in some cases because the second light transmitting layer 105 is not essential in the present embodiment.

According to example embodiments, the second light transmitting layer 105 may have a flat plate shape. According to example embodiments, the top and bottom surfaces of the second light transmitting layer 105 may be substantially flat. According to example embodiments, a thickness of the second light transmitting layer 105 may be substantially constant over the entire surface thereof.

According to example embodiments, the first and second light transmitting layers 101 and 105 may be substantially transparent to the lights UL1, UL2, and UL3. The lights UL1, UL2, and UL3 may be generated by a plurality of mesa structures 120 respectively including the first epitaxial patterns 121M, the second epitaxial patterns 123, the third epitaxial patterns 125, and the fourth epitaxial patterns 127 and may be emitted to the outside through the second light transmitting layer 105 and the first light transmitting layer 101.

According to example embodiments, the first and second light transmitting layers 101 and 105 may have different refractive indices. According to example embodiments, a refractive index of the first light transmitting layer 101 may be less than a refractive index of the second light transmitting layer 105. According to example embodiments, the refractive index of the first light transmitting layer 101 may be greater than a refractive index of air. According to example embodiments, the refractive index of the first light transmitting layer 101 may be in a range of about 1.5 to about 2. According to example embodiments, the refractive index of the second transmissive layer 105 may be in a range of about 2 to about 2.5.

The first epitaxial layer 121 including the first epitaxial patterns 121M may be on the second light transmitting layer 105. The second epitaxial patterns 123 may be on the first epitaxial patterns 121M. The third epitaxial patterns 125 may be on the second epitaxial patterns 123. The fourth epitaxial patterns 127 may be on the third epitaxial patterns 125. The first to fourth epitaxial patterns 121M, 123, 125, and 127 may form or make up the plurality of mesa structures 120.

According to example embodiments, the first epitaxial patterns 121M may be separated from each other in the Y direction. According to example embodiments, the second epitaxial patterns 123 may be separated from each other in the Y direction. According to example embodiments, the third epitaxial patterns 125 may be separated from each other in the Y direction. According to example embodiments, the fourth epitaxial patterns 127 may be separated from each other in the Y direction.

In a non-limiting example, the first epitaxial layer 121 may include an n-type nitride semiconductor layer, and the third and fourth epitaxial patterns 125 and 127 may each include a p-type nitride semiconductor layer. For example, the first epitaxial layer 121 may include a p-type nitride semiconductor layer, and the third and fourth epitaxial patterns 125 and 127 may each include an n-type nitride semiconductor layer.

According to some embodiments, the first epitaxial layer 121 and the second to fourth epitaxial patterns 123, 125, and 127 may each include a material that satisfies a composition formula of AlₓIn_{y}Ga_{(1-x-y)}N (where 0≤x≤1, 0≤y≤1, and 0≤x+y≤1). For example, the first epitaxial layer 121 and the second and third epitaxial patterns 123 and 125 may each include a material such as AlGaN or AlInGaN. According to example embodiments, the fourth epitaxial patterns 127 may include GaN. However, the disclosure is not limited thereto, and the fourth epitaxial patterns 127 may include Al with a low composition ratio.

An Al composition ratio of the first epitaxial layer 121 may be controlled according to a peak wavelength of light emitted from the second epitaxial patterns 123. When energies of the lights UL1, UL2, and UL3 emitted from the second epitaxial patterns 123 are greater than an energy bandgap of the first epitaxial layer 121, the lights UL1, UL2, and UL3 are absorbed by the first epitaxial layer 121, and thus, light extraction efficiency of the light emitting device 100 may be reduced. Accordingly, the Al composition ratio of the first epitaxial layer 121 may be selected such that the first epitaxial layer 121 has a greater energy bandgap than energy corresponding to peak wavelengths of the lights UL1, UL2, and UL3 emitted from the second epitaxial patterns 123.

For example, when the peak wavelength of the light emitted from the second epitaxial patterns 123 is about 275 nm, the first epitaxial layer 121 may include a nitride-based semiconductor with an Al composition ratio of about 30% or more. According to example embodiments, Al composition ratio of each of the second and third epitaxial patterns 123 and 125 may be greater than or equal to 30%. In example embodiments, the Al composition ratio of each of the first epitaxial layer 121 and the second and third epitaxial patterns 123 and 125 may be greater than or equal to about 45%.

The third epitaxial patterns 125 may include a nitride-based semiconductor with an energy bandgap of about 3.0 eV to about 4.0 eV. The fourth epitaxial patterns 127 include p-GaN, and thus, ohmic contacts between the fourth epitaxial patterns 127 and the second electrode layer 163 may be readily formed. Accordingly, contact resistance between the fourth epitaxial patterns 127 and the second electrode layer 163 may be reduced, and energy efficiency of the light emitting device 100 may be increased.

In a non-limiting example, the first epitaxial layer 121 may include AlGaN doped with an n-type dopant, and the third epitaxial patterns 125 may include AlGaN doped with a p-type dopant, and the fourth epitaxial patterns 127 may include GaN doped with a p-type dopant. The n-type dopant may include, for example, Si, Ge, or Sn, and the p-type dopant may include Mg, Sr, or Ba.

The second epitaxial patterns 123 may include active layers. The second epitaxial patterns 123 may be between the first epitaxial patterns 121M of the first epitaxial layer 121 and the third epitaxial patterns 125. The second epitaxial patterns 123 may emit the lights UL1, UL2, and UL3 with predetermined energies due to recombination of electrons and holes. The second epitaxial patterns 123 may include a material with an energy band gap less than energy band gaps of the first epitaxial layer 121 and the third epitaxial patterns 125.

For example, when each of the first epitaxial layer 121 and the third epitaxial patterns 125 is an AlGaN-based compound semiconductor, the second epitaxial patterns 123 may include an AlInGaN-based compound semiconductor with a less energy band gap than an energy band gap of AlGaN. According to some embodiments, the second epitaxial patterns 123 may include a multiple quantum well (MQW) structure in which quantum well layers and quantum barrier layers are alternately stacked. According to some embodiments, the second epitaxial patterns 123 may include a structure in which AlInGaN and AlGaN are alternately stacked. However, the disclosure is not limited thereto, and the second epitaxial patterns 123 may include a single quantum well (SQW) structure.

Each of the plurality of mesa structures 120 may have an increasing horizontal width (a Y-direction width) towards the first light transmitting layer 101 in the Z direction. For example, a width of a first portion of each of the plurality of mesa structures 120 may be greater than a width of a second portion farther from the first light transmitting layer 101 than the first portion.

In example embodiments, the passivation patterns 130 may include an insulating material. According to example embodiments, the passivation patterns 130 may include an oxides and a nitride. According to example embodiments, the passivation patterns 130 may include any one of an aluminum oxide, an aluminum nitride, a silicon oxide, and a silicon nitride. In example embodiments, the passivation patterns 130 may include a thermal oxide. According to example embodiments, the passivation patterns 130 may include any one of SiO₂ and Al₂O₃.

According to example embodiments, the passivation patterns 130 may have a conformal shape. According to example embodiments, thicknesses of the passivation patterns 130 may be in a range of about 1 nm to about 100 nm. According to example embodiments, the thicknesses of each of the passivation patterns 130 may be greater than or equal to about 10 nm.

According to example embodiments, the passivation patterns 130 cover side surfaces of the plurality of mesa structures 120, and thus, light extraction efficiency of the light emitting device 100 may be prevented from decreasing due to damage to the plurality of mesa structures 120. According to example embodiments, the passivation patterns 130 may prevent non-emission recombination from occurring in the second epitaxial patterns 123.

According to example embodiments, the passivation patterns 130 may insulate the adjacent mesa structures 120 from each other. According to example embodiments, the passivation patterns 130 may prevent side surfaces of the first to fourth epitaxial patterns 121M, 123, 125, and 127 included in the adjacent mesa structures 120 from being contaminated by by-products generated during an etching process.

According to example embodiments, a horizontal width MW (for example, a Y-direction width) of each of the plurality of mesa structures 120 may be in a range of about 5 μm to about 30 μm. In example embodiments, the horizontal width MW of each of the plurality of mesa structures 120 may be less than or equal to about 27 μm. In example embodiments, the horizontal width MW of each of the plurality of mesa structures 120 may be less than or equal to about 24 μm. In example embodiments, the horizontal width MW of each of the plurality of mesa structures 120 may be less than or equal to about 21 μm. In example embodiments, the horizontal width MW of each of the plurality of mesa structures 120 may be less than or equal to about 18 μm. In example embodiments, the horizontal width MW of each of the plurality of mesa structures 120 may be less than or equal to about 15 μm.

The aforementioned horizontal width MW of each of the plurality of mesa structures 120 may include the greatest horizontal width of the plurality of mesa structures 120 in a separation direction (that is, the Y direction) of the plurality of mesa structures 120. As described above, the plurality of mesa structures 120 have a tapered structure, and the horizontal width MW of each of the plurality of mesa structures 120 may be the same as Y-direction widths of the first epitaxial patterns 121M. Accordingly, the aforementioned ranges of the horizontal width MW may be equally applied to the Y-direction widths of the first epitaxial patterns 121M.

According to example embodiments, distances MS (for example, a Y-direction distance) between the plurality of mesa structures 120 may be in a range of about 5 μm to about 30 μm. According to example embodiments, the distances MS between the plurality of mesa structures 120 may each be less than or equal to about 27 μm. According to example embodiments, the distances MS between the plurality of mesa structures 120 may each be less than or equal to about 24 μm. According to example embodiments, the distances MS between the plurality of mesa structures 120 may each be less than or equal to about 18 μm. According to example embodiments, the distances MS between the plurality of mesa structures 120 may each be less than or equal to about 15 μm.

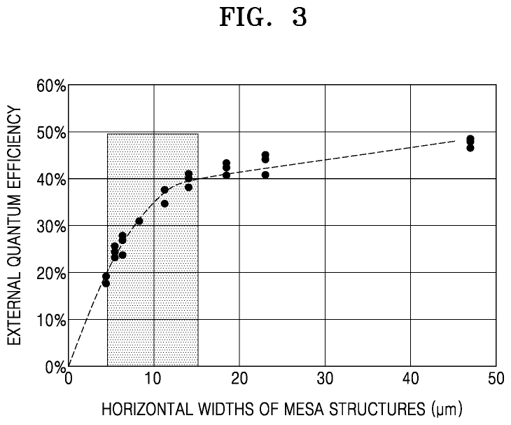

FIG. 3 is a graph illustrating external quantum efficiency of the light emitting device 100 according to the horizontal width MW of each of the plurality of mesa structures 120 according to an example embodiment.

Referring to FIGS. 1 to 3, it can be seen that external quantum efficiency of the light emitting device 100 is rapidly decreased when the horizontal width MW of each of the plurality of mesa structures 120 is less than or equal to about 5 μm. According to example embodiments, the external quantum efficiency of the light emitting device 100 may be prevented from decreasing by providing the plurality of mesa structures 120 having the horizontal width MW of about 5 μm or more.

Referring back to FIGS. 1 and 2, in example embodiments, a side inclination angle θM of each of the plurality of mesa structures 120 may be in a range of about 50 degrees to about 90 degrees. Here, the side inclination angle θM of each of the plurality of mesa structures 120 may be an angle between each of the side surfaces of the plurality of mesa structures 120 and a lower surface of the second electrode layer 163. According to example embodiments, the side inclination angle θM of each of the plurality of mesa structures 120 may be greater than or equal to about 55 degrees. According to example embodiments, the side inclination angle θM of each of the plurality of mesa structures 120 may be greater than or equal to about 60 degrees. According to example embodiments, the side inclination angle θM of each of the plurality of mesa structures 120 may be greater than or equal to about 65 degrees. According to example embodiments, the side inclination angle θM of each of the plurality of mesa structures 120 may be greater than or equal to about 70 degrees. According to example embodiments, the side inclination angle θM of each of the plurality of mesa structures 120 may be greater than or equal to about 75 degrees. According to example embodiments, the side inclination angle θM of each of the plurality of mesa structures 120 may be greater than or equal to about 80 degrees. According to example embodiments, the side inclination angle θM of each of the plurality of mesa structures 120 may be greater than or equal to about 85 degrees.

The passivation patterns 130 may each have a conformal shape, and thus, an angle between each of the passivation patterns 130 and a lower surface of the second electrode layer 163 may be substantially the same as the side inclination angle θM. Accordingly, a range of the side inclination angle θM may be similarly applied to the angle between each of the passivation patterns 130 and the lower surface of the second electrode layer 163.

In a process of patterning the plurality of mesa structures 120 having a width of several tens of micrometers or less as described below, side inclinations of the plurality of mesa structures 120 may have relatively large angles greater than or equal to 50 degrees. According to example embodiments, the side inclination angle θM of each of the plurality of mesa structures 120 is greater than or equal to about 50 degrees. Thus, areas occupied by the second epitaxial patterns 123 in the light emitting device 100 may increase, thereby enhancing light emission efficiency of the light emitting device 100.

An LED chip for generating blue light may have a roughened space between a growth substrate and a buffer layer, and thus, light extraction efficiency thereof is increased. However, an LED chip for generating UV light has a problem in that a buffer layer including an aluminum nitride is not bonded to the roughened surface of the growth substrate. According to example embodiments, by providing the plurality of mesa structures 120 having a relatively small width ranging from about 5 μm to about 30 μm, light extraction efficiency may be increased even when the growth substrate is not roughened.

The fourth epitaxial patterns 127 for forming ohmic contacts have high absorption rates for the lights UL1, UL2, and UL3 due to energy bandgap characteristics. Accordingly, light generated by the second epitaxial patterns 123 and transferred directly to the fourth epitaxial patterns 127 and the lights UL1, UL2, and UL3 generated by the second epitaxial patterns 123 and reflected from interfaces of the first and second light transmitting layers 101 and 105 to be transferred to the fourth epitaxial patterns 127 may be absorbed by the fourth epitaxial patterns 127.

Paths of the lights UL1, UL2, and UL3 generated by the second epitaxial patterns 123 are indicated by arrows in FIG. 1. The light UL1 generated by the second epitaxial patterns 123 may proceed to the second light transmitting layer 105 without interacting with the passivation patterns 130. A direction angle of the light UL1 may be referred to as a first angle θ1. The light UL2 generated by the second epitaxial patterns 123 may proceed to the second light transmitting layer 105 without interacting with the passivation patterns 130 but may proceed through a path having the largest angle with a normal line of the first and second light transmitting layers 101 and 105. A direction angle of the light UL2 may be referred to as a second angle θ2. The second angle θ2 may be greater than or equal to the first angle θ1. The light UL3 may be generated by the second epitaxial patterns 123, reflected by the passivation patterns 130, and then emitted to the outside through the first and second light transmitting layers 101 and 105. The direction angle of the light UL3 may be the third angle θ3.

According to example embodiments, the horizontal width MW of each of the plurality of mesa structures 120 is less than or equal to 30 μm, thus, the direction angles θ1 and θ2 of the lights UL1 and UL2 generated by the second epitaxial patterns 123 and directed to the second light transmitting layer 105 without interacting with the passivation patterns 130 may be less than a first critical angle of an interface between the first light transmitting layer 101 and the second light transmitting layer 105 and a second critical angle of an interface between the first light transmitting layer 101 and the outside (for example, an air layer). Accordingly, the lights UL1 and UL2 may be prevented from being fully reflected from the interface between the first light transmitting layer 101 and the second light transmitting layer 105 and the interface between the first light transmitting layer 101 and the outside to direct to the fourth epitaxial patterns 127.

The light UL3 generated by the second epitaxial patterns 123 and transferred to the passivation patterns 130 may be reflected by the passivation patterns 130. The direction angle θ3 of the light UL3 reflected by the passivation patterns 130 may be less than the first critical angle of the interface between the first light transmitting layer 101 and the second light transmitting layer 105 and the second critical angle of the interface between the first light transmitting layer 101 and the outside (for example, an air layer).

According to example embodiments, the passivation patterns 130 may limit the direction angles θ1, θ2, and θ3 of the lights UL1, UL2, and UL3 generated by the second epitaxial patterns 123. According to example embodiments, the passivation patterns 130 may not interact with the lights UL1 and UL2 respectively having the direction angles θ1 and θ2 less than the first critical angle of the interface between the first light transmitting layer 101 and the second light transmitting layer 105 and the second critical angle of the interface between the first light transmitting layer 101 and the outside (for example, an air layer). According to example embodiments, the passivation patterns 130 may reflect the light UL3 having the direction angle θ3 greater than any one of the first critical angle of the interface between the first light transmitting layer 101 and the second light transmitting layer 105 and the second critical angle of the interface between the first light transmitting layer 101 and the outside (for example, an air layer), thereby directing the light UL3 at an angle less than the first critical angle of the interface between the first light transmitting layer 101 and the second light transmitting layer 105 and the second critical angle of the interface between the first light transmitting layer 101 and the outside (for example, an air layer)

In example embodiments, the passivation patterns 130 may partially cover a surface of the first epitaxial layer 121 between the plurality of mesa structures 120. According to example embodiments, the passivation patterns 130 may expose upper surfaces of the plurality of mesa structures 120.

In example embodiments, the passivation patterns 130 may cover side surfaces of the first to fourth epitaxial patterns 121M, 123, 125, and 127. According to example embodiments, the passivation patterns 130 may expose upper surfaces of the fourth epitaxial patterns 127.

In example embodiments, the passivation patterns 130 may partially expose a surface of the first epitaxial layer 121 between the plurality of mesa structures 120. In example embodiments, the contact layer 140 may be formed on the exposed surface of the first epitaxial layer 121 between the plurality of mesa structures 120. In example embodiments, the contact layer 140 may include Au, Ni, Pt, or so on.

The filling insulating layer 150 may fill spaces between the plurality of mesa structures 120. The filling insulating layer 150 may cover the passivation patterns 130 and the contact layer 140. The filling insulating layer 150 may include an insulating material. The filling insulating layer 150 may be formed through either a thermal oxidation process or a plasma oxidation process. The filling insulating layer 150 may include any one of SiO₂, Al₂O₃, ZrO₂, TiO₂, HfO₂, and Nb₂O₅.

In example embodiments, the filling insulating layer 150 may include the same material as the passivation patterns 130. In this case, the filling insulating layer 150 may be integrated with the passivation patterns 130 to form a continuous layer.

In example embodiments, the filling insulating layer 150 may include a material different from a material of the passivation patterns 130. In this case, the filling insulating layer 150 may have a separate structure different from a structure of the passivation patterns 130.

The first electrode layer 161 may be on the contact layer 140, and the second electrode layer 163 may be on the plurality of mesa structures 120 and the filling insulating layer 150. The first electrode layer 161 may be electrically connected to the first epitaxial layer 121 through the contact layer 140. The second electrode layer 163 may be electrically connected to the third epitaxial patterns 125 through the fourth epitaxial patterns 127. The first electrode layer 161 may include a cathode of a light emitting device. The second electrode layer 163 may include an anode of a light emitting device. In example embodiments, the first and second electrode layers 161 and 163 may include metal materials such as Ni and Au. In example embodiments, the first and second electrode layers 161 and 163 may include pads for bonding with solder, etc.

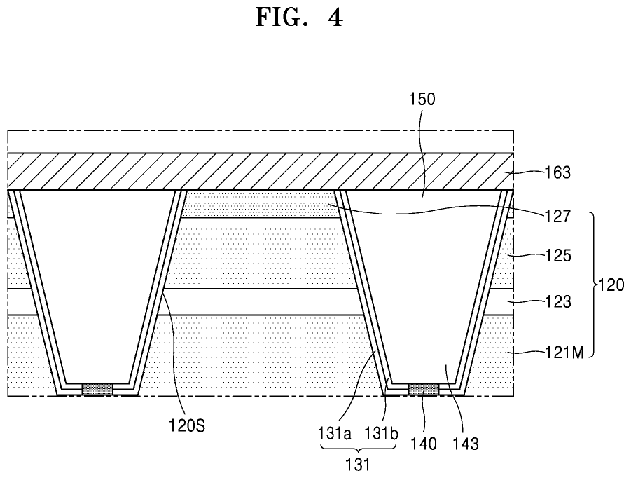

FIG. 4 is a partial cross-sectional view of the passivation patterns 130 according to an example embodiment, which illustrates a portion corresponding to FIG. 2.

That is, FIG. 4 may depict an enlarged view of a portion POR1 of FIG. 1.

Referring to FIG. 4, the passivation patterns 131 may each have a double-layer structure. The passivation patterns 131 may each include a first passivation pattern 131a and a second passivation pattern 131b. In example embodiments, the first passivation pattern 131a may be formed through a thermal oxidation process, and the second passivation pattern 131b may be formed through a plasma oxidation process.

In a non-limiting example, the first passivation pattern 131a may include the same material as the second passivation pattern 131b. For example, the first passivation pattern 131a and the second passivation pattern 131b may each include Al₂O₃ or SiO₂. In this case, the first passivation pattern 131a and the second passivation pattern 131b may be integrated to form a continuous layer.

In a non-limiting example, the first passivation pattern 131a may include a material different from a material of the second passivation pattern 131b. For example, the first passivation pattern 131a may include SiO₂, and the second passivation pattern 131b may include Al₂O₃. In another example, the first passivation pattern 131a may include Al₂O₃, and the second passivation pattern 131b may include SiO₂. In this case, the first passivation pattern 131a may be formed as a layer different from the second passivation pattern 131b.

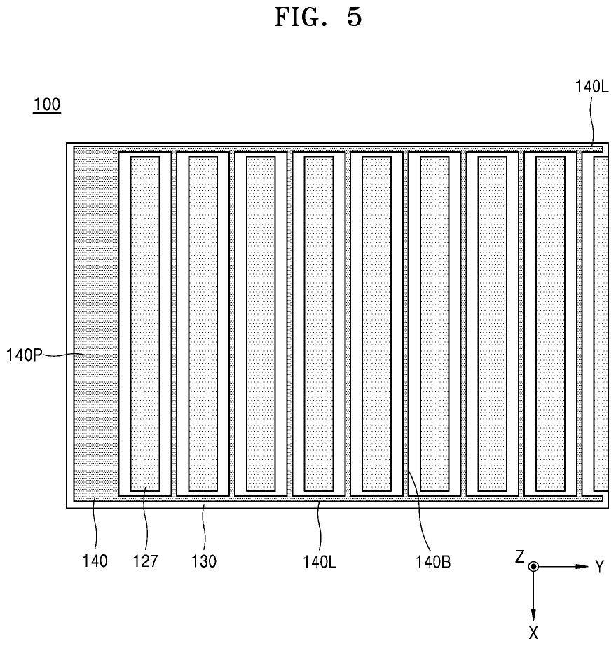

FIG. 5 is a plan view illustrating the light emitting device 100 according to an example embodiment. For the sake of convenient understanding, the first and second electrode layers 161 and 163 are omitted.

Referring to FIGS. 1 and 5, in example embodiments, the plurality of mesa structures 120 may have a line shape extending in the X direction. Similarly, the first to fourth epitaxial patterns 121M, 123, 125, and 127 may have a line shape extending in the X direction. The plurality of mesa structures 120 may be separated from each other in the Y direction. Arrangement of the plurality of mesa structures 120 may be referred to as a line-and-space structure.

The contact layer 140 may include branches 140B extending between the adjacent mesa structures 120, a pad portion 140P in contact with the first electrode layer 161, and a line portion 140L connecting the branches 140B to the pad portion 140P. Power transmitted from the first electrode layer 161 through the pad portion 140P may be uniformly transmitted to the first epitaxial layer 121 through the branches 140B extending between the plurality of mesa structures 120. In example embodiments, the contact layer 140 may horizontally surround the plurality of mesa structures 120.

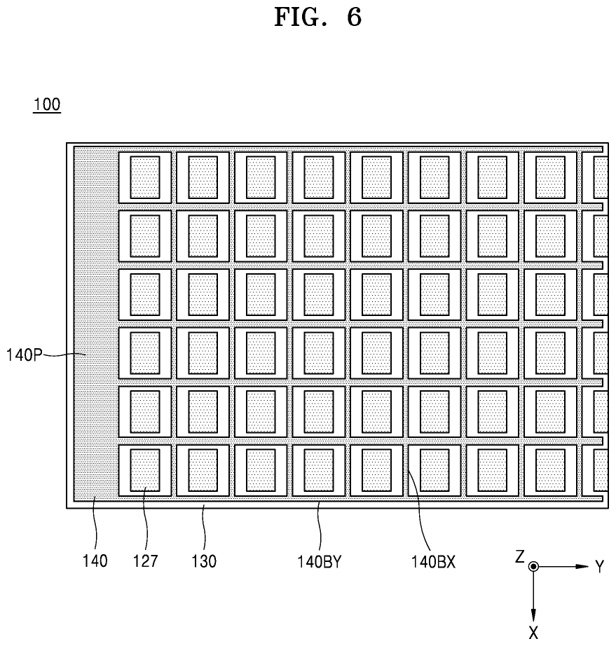

FIG. 6 is a plan view illustrating the light emitting device 100 according to example embodiments. For the sake of convenient understanding, the first and second electrode layers 161 and 163 are omitted.

Referring to FIGS. 1 and 6, in example embodiments, the plurality of mesa structures 120 may have an island shape. Similarly, the first to fourth epitaxial patterns 121M, 123, 125, and 127 may have an island shape. According to example embodiments, the plurality of mesa structures 120 may be arranged in the X and Y directions. According to example embodiments, the plurality of mesa structures 120 may form a matrix.

The contact layer 140 may include branches 140BX and 140BY extending between the adjacent mesa structures 120 and a pad portion 140P in contact with the first electrode layer 161. Some of the branches 140BX may extend in the X direction, and some of the branches 140BY may extend in the Y direction. Power transmitted from the first electrode layer 161 through the pad portion 140P may be uniformly transmitted to the first epitaxial layer 121 through the branches 140BX and 140BY extending between the plurality of mesa structures 120. In example embodiments, the contact layer 140 may horizontally surround the plurality of mesa structures 120.

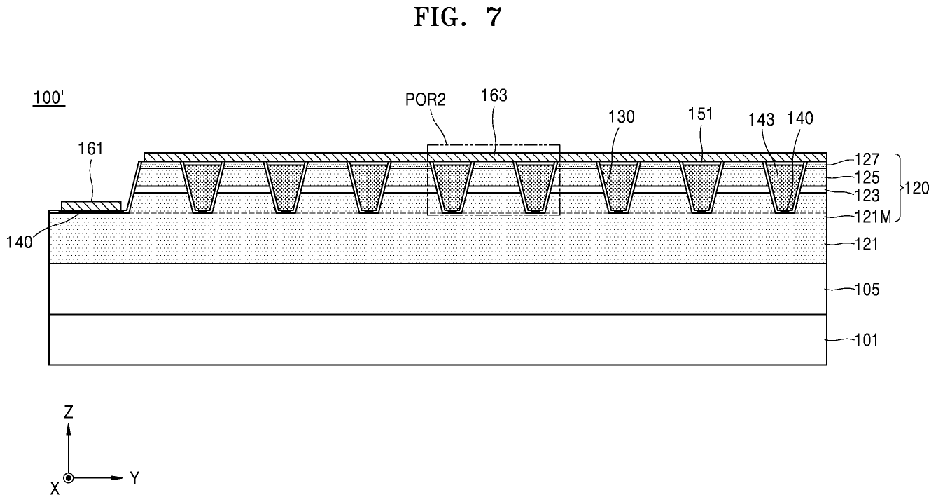

FIG. 7 is a cross-sectional view illustrating a light emitting device 100′ according to an example embodiment.

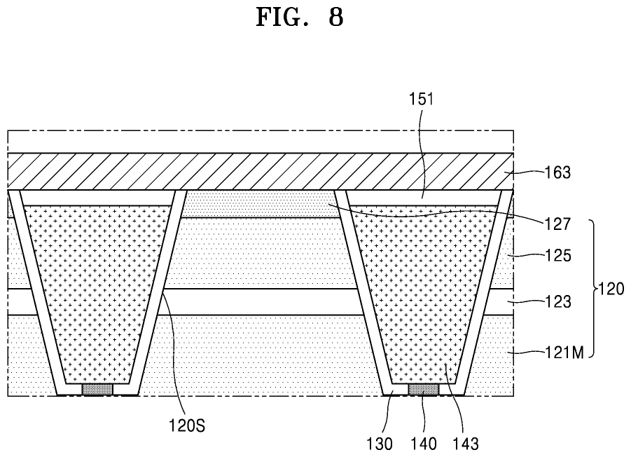

FIG. 8 is an enlarged cross-sectional view of a portion POR2 of FIG. 7 according to an example embodiment.

Referring to FIGS. 7 and 8, the light emitting device 100′ may include a first light transmitting layer 101, a second light transmitting layer 105, a first epitaxial layer 121 including first epitaxial patterns 121M, second epitaxial patterns 123, third epitaxial patterns 125, fourth epitaxial patterns 127, passivation patterns 130, a contact layer 140, a reflective electrode 143, a cover insulating layer 151, a first electrode layer 161, and a second electrode layer 163.

The first light transmitting layer 101, the second light transmitting layer 105, the first epitaxial layer 121 including the first epitaxial patterns 121M, the second epitaxial patterns 123, the third epitaxial patterns 125, the fourth epitaxial patterns 127, the passivation patterns 130, the contact layer 140, the first electrode layer 161, and the second electrode layer 163 are respectively substantially the same as the first light transmitting layer 101, the second light transmitting layer 105, the first epitaxial layer 121 including the first epitaxial patterns 121M, the second epitaxial patterns 123, the third epitaxial patterns 125, the fourth epitaxial patterns 127, the passivation patterns 130, the contact layer 140, the first electrode layer 161, and the second electrode layer 163, which are described with reference to FIGS. 1 and 2, and thus redundant descriptions thereof are omitted.

According to example embodiments, the reflective electrode 143 may fill spaces between adjacent mesa structures 120. The reflective electrode 143 may be in contact with the contact layer 140. The reflective electrode 143 may be electrically connected to the contact layer 140.

The reflective electrode 143 may include a conductive material. The reflective electrode 143 may include a metal material. The reflective electrode 143 may include a material with high reflectance for the lights UL1, UL2, and UL3 (see FIG. 1) generated by the second epitaxial patterns 123, such as, Al or Ag.

The reflective electrode 143 may be separated from a mesa structure 120 with the passivation patterns 130 formed therebetween. The reflective electrode 143 may be insulated from the mesa structure 120 by the passivation patterns 130.

According to example embodiments, light extraction efficiency of the light emitting device 100′ may be increased by the reflective electrode 143. In addition, resistances of the contact layer 140 and the reflective electrode 143 are reduced, and thus, power efficiency of the light emitting device 100′ may be increased.

The cover insulating layer 151 may cover an upper surface of the reflective electrode 143. Accordingly, the reflective electrode 143 may be surrounded by the cover insulating layer 151 and the passivation patterns 130.

The cover insulating layer 151 may include an insulating material. The cover insulating layer 151 may be formed through either a thermal oxidation process or a plasma oxidation process. The cover insulating layer 151 may include any one of SiO₂, Al₂O₃, ZrO₂, TiO₂, HfO₂, and Nb₂O₅.

In example embodiments, the cover insulating layer 151 may include the same material as the passivation patterns 130. In this case, the cover insulating layer 151 may be integrated with the passivation patterns 130 to form a continuous layer.

In example embodiments, the cover insulating layer 151 may include a material different from a material of the passivation patterns 130. In this case, the cover insulating layer 151 may have a separate structure different from a structure of the passivation patterns 130.

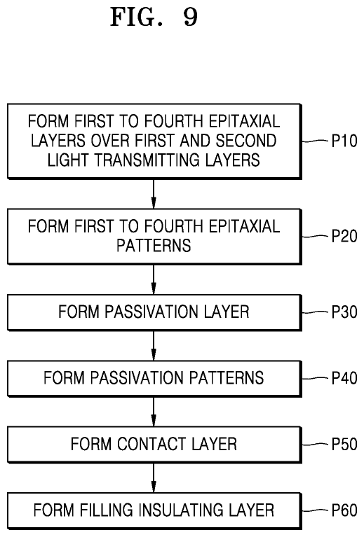

FIG. 9 is a flowchart of a method of manufacturing a light emitting device according to an example embodiment.

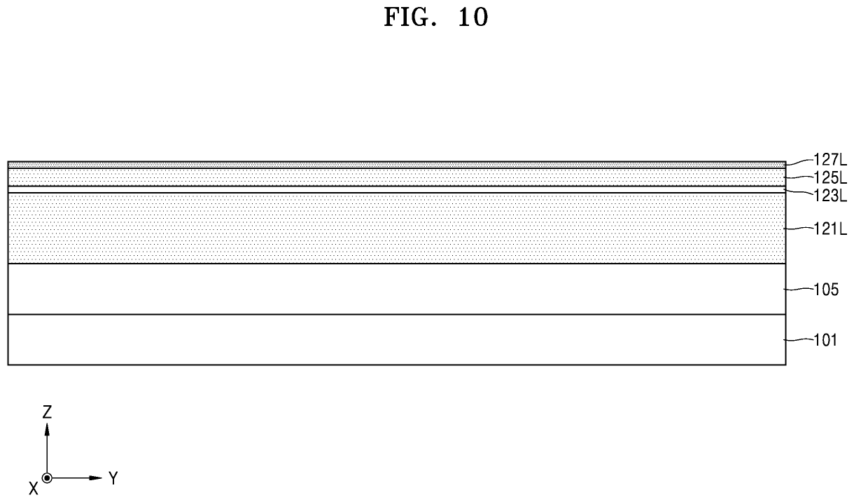

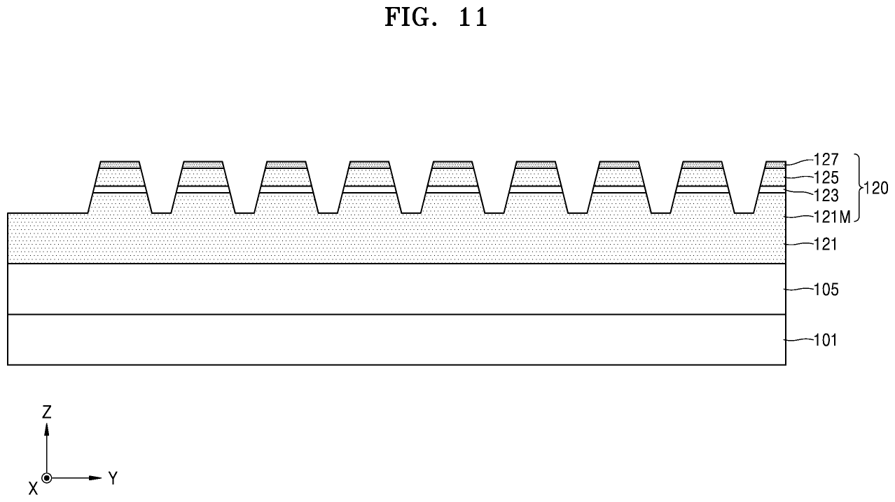

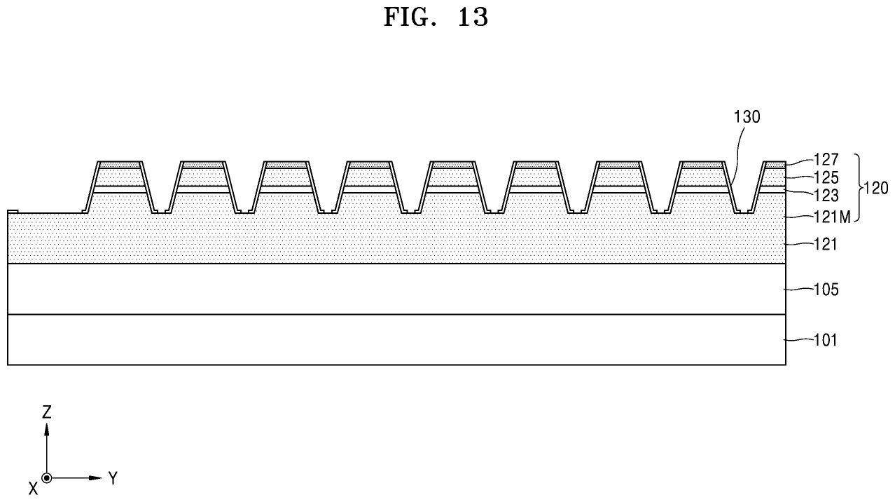

FIGS. 10 to 15 are cross-sectional views illustrating a method of manufacturing a light emitting device, according to example embodiments.

Referring to FIGS. 9 and 10, first to fourth epitaxial layers 121L, 123L, 125L, and 127L may be formed over first and second light transmitting layers 101 and 105 in operation P10.

The first light transmitting layer 101 may include a growth substrate including sapphire as described with reference to FIG. 1.

The first light transmitting layer 101 may include a growth substrate, and composition, configuration, and a shape thereof may be substantially the same as the composition, configuration, and shape described with reference to FIG. 1.

The second light transmitting layer 105 may include substantially the same composition as the second light transmitting layer 105 described with reference to FIG. 1. According to some embodiments, the second light transmitting layer 105 may be formed by at least one method of MOCVD, hydrogen vapor phase epitaxy (HVPE), and molecular beam epitaxy (MBE). According to some other example embodiments, the second light transmitting layer 105 may be formed through a thin film growth process including AlN after a seed layer is provided through a sputtering process of an aluminum nitride such as AlN.

According to some embodiments, the second light transmitting layer 105 may be formed by performing chemical vapor deposition (CVD) at a temperature of about 400° C. to about 1300° C. by using an Al source and an N source.

Subsequently, the first to fourth epitaxial layers 121L, 123L, 125L, and 127L may be formed by performing MOCVD, HVPE, and MBE while changing atmosphere gas and source gas in a reactor. In example embodiments, the first to fourth epitaxial layers 121L, 123L, 125L, and 127L may be formed through an epitaxial growth process.

Referring to FIGS. 9 to 11, the first to fourth epitaxial layers 121L, 123L, 125L, and 127L may be etched to form first to fourth epitaxial patterns 121M, 123, 125, and 127 in operation P20.

In example embodiments, the first to fourth epitaxial layers 121L, 123L, 125L, and 127L may be patterned by anisotropic dry etching. The first to fourth epitaxial patterns 121M, 123, 125, and 127 may constitute a plurality of mesa structures 120. After the first to fourth epitaxial patterns 121M, 123, 125, and 127 are formed, side surfaces (that is, the side surfaces of the plurality of mesa structures 120) of the first to fourth epitaxial patterns 121M, 123, 125, and 127 may be processed by using any one of KOH and tetramethylammonium hydroxide (TMAH). Accordingly, a portion of side surfaces of the first to fourth epitaxial patterns 121M, 123, 125, and 127 (that is, the side surfaces of the plurality of mesa structures 120) damaged during an etching process may be removed.

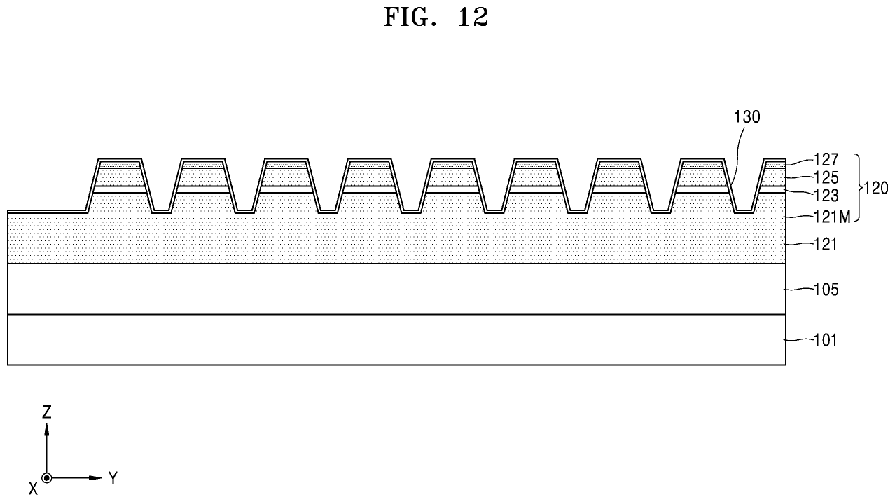

Referring to FIGS. 9 and 12, a passivation layer 130L may be formed in operation P30.

According to example embodiments, the passivation layer 130L may include any one of an oxide and a nitride. According to example embodiments, the passivation layer 130L may have a uniform thickness. A thickness of the passivation layer 130L may range from about 1 nm to about 100 nm.

In a non-limiting example, the passivation layer 130L may be formed through a thermal oxidation process. In another example, the passivation layer 130L may be formed by performing a plasma oxidation process after the thermal oxidation process is performed. For example, after a portion of the passivation layer 130L having a thickness of about 1 nm to about 10 nm is formed by a thermal oxidation process, a portion of the passivation layer 130L having a thickness of about 90 nm to about 99 nm may be formed through a plasma oxidation process.

Referring to FIGS. 9, 12, and 13, the passivation layer 130L may be etched to form passivation patterns 130 in operation P40.

In example embodiments, the portion of passivation layer 130L may be removed through a dry etching process in which a photomask is used. The passivation patterns 130 may be formed by partially removing the passivation layer 130L to expose a surface of the first epitaxial layer 121 for forming the pad portion 140P (see FIG. 5) of the contact layer 140 (see FIG. 5) and a surface of the first epitaxial layer 121 between the plurality of mesa structures 120.

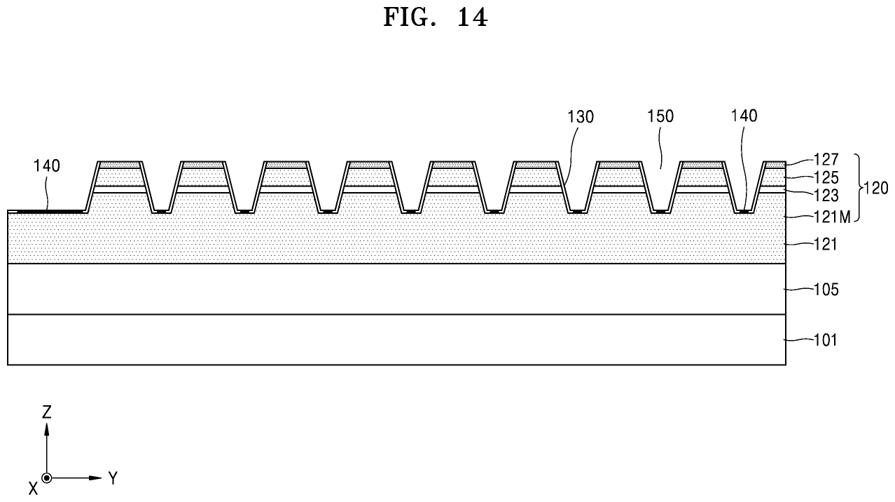

Referring to FIGS. 9 and 14, a contact layer 140 may be formed in operation P50. According to example embodiments, the contact layer 140 may be formed by metal CVD or metal sputtering. According to example embodiments, the passivation patterns 130 are formed by etching process using a photoresist pattern as a mask pattern in operation P40, a conformal metal material layer is provided thereon, and then the photoresist patterns are removed through a lift-off process, and thus, the contact layer 140 may be formed.

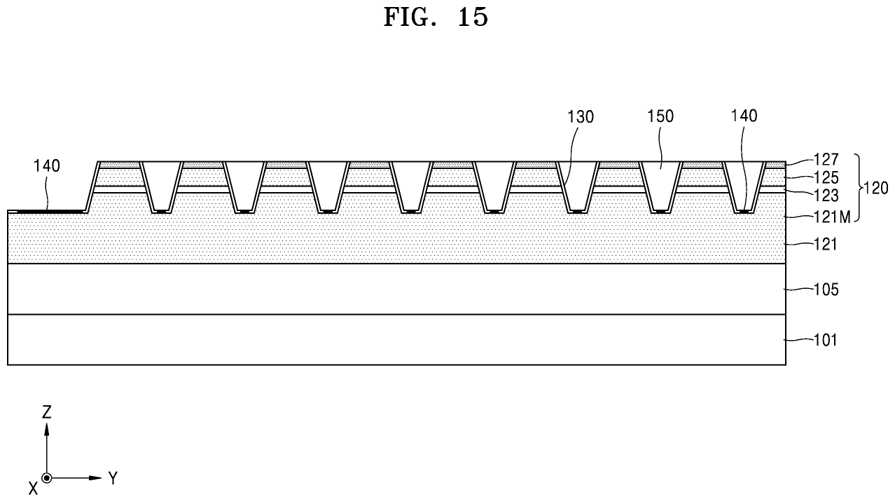

Referring to FIGS. 9 and 15, a filling insulating layer 150 may be formed in operation P60. After an insulating material layer is formed to sufficiently fill a space between adjacent mesa structures 120, the insulating material layer is planarized to expose the fourth epitaxial patterns 127, and thus, the filling insulating layer 150 may be formed. The insulating material layer may be formed through either a plasma oxidation process or a thermal oxidation process. Subsequently, referring to FIG. 1, first and second electrode layers 161 and 163 may be formed.

While the disclosure has been particularly shown and described with reference to embodiments thereof, it will be understood that various changes in form and details may be made therein without departing from the spirit and scope of the following claims.

1. A light emitting device comprising:
a first light transmitting layer;
a second light transmitting layer provided on the first light transmitting layer;
a plurality of mesa structures provided on the second light transmitting layer and configured to generate light in an ultraviolet band; and
passivation patterns provided on side surfaces of the plurality of mesa structures,
wherein each of the plurality of mesa structures comprises:
a first epitaxial pattern comprising an aluminum gallium nitride,
a second epitaxial pattern provided on the first epitaxial pattern and comprising an aluminum gallium nitride,
a third epitaxial pattern provided on the second epitaxial pattern and comprising an aluminum gallium nitride, and
a fourth epitaxial pattern provided on the third epitaxial pattern and comprising a gallium nitride, and
wherein a horizontal width of each of the plurality of mesa structures is in a range of about 5 μm to about 30 μm.

2. The light emitting device of claim 1, wherein the horizontal width of each of the plurality of mesa structures is less than or equal to 15 μm.

3. The light emitting device of claim 1, wherein a distance between adjacent mesa structures of the plurality of mesa structures is in a range of about 5 μm to about 30 μm.

4. The light emitting device of claim 1, wherein each of the passivation patterns comprises Al₂O₃.

5. The light emitting device of claim 1, wherein the passivation patterns are configured to reflect light, among lights generated by the second epitaxial pattern, having a direction angle greater than a critical angle of an interface between the first light transmitting layer and the second light transmitting layer.

6. The light emitting device of claim 1, wherein the passivation patterns are formed through a thermal oxidation process.

7. The light emitting device of claim 1, further comprising a filling insulating layer configured to cover the passivation patterns and to fill a space between the plurality of mesa structures.

8. The light emitting device of claim 7, wherein the filling insulating layer comprises a material different from a material of the passivation patterns.

9. The light emitting device of claim 1, further comprising a reflective electrode layer configured to cover the passivation patterns and to fill a space between the plurality of mesa structures.

10. The light emitting device of claim 9, wherein the passivation patterns are interposed between the plurality of mesa structures, and
wherein the reflective electrode layer is separated from the plurality of mesa structures with the passivation patterns interposed therebetween.

11.-14. (canceled)

15. A light emitting device comprising:
a first light transmitting layer comprising sapphire;
a second light transmitting layer comprising an aluminum nitride and provided on the first light transmitting layer;
a first epitaxial layer provided on the second light transmitting layer and comprising a plurality of first epitaxial patterns separated from each other in a first direction;
a plurality of second epitaxial patterns provided on the plurality of first epitaxial patterns, separated from each other in the first direction, and comprising a multiple quantum well (MQW) structure;
a plurality of third epitaxial patterns provided on the plurality of second epitaxial patterns and separated from each other in the first direction; and
a plurality of fourth epitaxial patterns provided on the plurality of third epitaxial patterns and separated from each other in the first direction,
wherein a width of each of the plurality of first epitaxial patterns in the first direction is in a range of about 5 μm to about 30 μm.

16. The light emitting device of claim 15, wherein the plurality of first epitaxial patterns, the plurality of second epitaxial patterns, the plurality of third epitaxial patterns, and each of the plurality of fourth epitaxial patterns have a line shape extending in a second direction perpendicular to the first direction.

17. The light emitting device of claim 16, further comprising:
a contact layer contacting the first epitaxial layer,
wherein the contact layer comprises:
a pad portion in contacting the a electrode layer, and
branches connected to the pad portion,
wherein the branches are interposed between the plurality of first epitaxial patterns, and
wherein each of the branches has a line shape extending in the second direction.

18. The light emitting device of claim 15, wherein each of the plurality of first epitaxial patterns and each of the plurality of fourth epitaxial patterns have an island shape.

19. The light emitting device of claim 18, further comprising:
a contact layer contacting the first epitaxial layer,
wherein the contact layer comprises:
a pad portion contacting the a electrode layer;
a plurality of first branches connected to the pad portion, the plurality of first branches being interposed between the plurality of first epitaxial patterns, wherein each of the plurality of first branches has a line shape extending in the first direction; and
a plurality of second branches connected to the plurality of first branches, the plurality of second branches being interposed between the plurality of first epitaxial patterns, wherein each of the plurality of second branches has a line shape extending in a second direction perpendicular to the first direction.

20. The light emitting device of claim 19, wherein the contact layer horizontally surrounds each of the plurality of first epitaxial patterns.

21. A light emitting device comprising:
a first light transmitting layer having a flat plate shape;
a second light transmitting layer provided on the first light transmitting layer and having a flat plate shape;
a first epitaxial layer provided on the second light transmitting layer and comprising a plurality of first epitaxial patterns separated from each other in a first direction;
a plurality of second epitaxial patterns provided on the plurality of first epitaxial patterns, separated from each other in the first direction, and comprising a multiple quantum well (MQW) structure;
a plurality of third epitaxial patterns provided on the plurality of second epitaxial patterns and separated from each other in the first direction; and
a plurality of fourth epitaxial patterns provided on the plurality of third epitaxial patterns and separated from each other in the first direction,
wherein the plurality of first epitaxial patterns, the plurality of second epitaxial patterns, and the plurality of third epitaxial patterns each comprise an aluminum gallium nitride,
wherein the plurality of fourth epitaxial patterns each comprise a gallium nitride,
wherein the plurality of first epitaxial patterns, the plurality of second epitaxial patterns, the plurality of third epitaxial patterns, and the plurality of fourth epitaxial patterns form a plurality of mesa structures separated from each other, and
wherein a width of each of the plurality of mesa structures in the first direction is in a range of about 5 μm to about 30 μm.

22. The light emitting device of claim 21, further comprising passivation patterns provided on side surfaces of the plurality of mesa structures.

23. The light emitting device of claim 22, further comprising:
a contact layer in contact with the first epitaxial layer;
wherein the contact layer comprises:
a pad portion, and
branches connected to the pad portion,
wherein the branches are interposed between the plurality of mesa structures, and
wherein each of the branches has a line shape extending in the first direction.

24. The light emitting device of claim 23, further comprising:
a first electrode layer in contact with the contact layer; and
a second electrode layer in contact with the plurality of fourth epitaxial patterns and separated from the contact layer.

25.-29. (canceled)
